(19) United States
(12) Patent Application Publication
(10) Pub. No.: US 2026/0153546 A1
(43) Pub. Date: Jun. 4, 2026

(54) EARLY ELECTROMAGNETIC WAVE ABNORMALITY DETECTION DEVICE AND METHOD OF CONTROLLING THE SAME

(71) Applicants: Hyundai Motor Company, Seoul (KR); Kia Corporation, Seoul (KR); NCT SOLUTIONS, Seoul (KR)

(72) Inventors: Jun-Byung CHAE, Hwaseong-si, Gyeonggi-do (KR); Yoon-Jong HUH, Seoul (KR); Ook KIM, Seoul (KR)

(73) Assignees: Hyundai Motor Company, Seoul (KR); Kia Corporation, Seoul (KR); NCT SOLUTIONS, Seoul (KR)

(21) Appl. No.: 18/956,519

(22) Filed: Nov. 22, 2024

(30) Foreign Application Priority Data
Dec. 14, 2023 (KR) 10-2023-0182316

(51) Int. Cl. G01R 29/08

(52) U.S. Cl. CPC G01R 29/0814; G01R 29/0878; G01R 29/0892

(57) ABSTRACT

Provided is an early electromagnetic wave abnormality detection device in which a frequency detector including a fast response rate and a function of classifying electromagnetic waves and generating a warning signal by analyzing the detection signal are embedded in a single chip device, whereby an electromagnetic wave abnormality is detected early. A receiving end receives an antenna signal from an antenna block and generates a conversion signal. A switch changes a gain according to characteristics of the antenna signal and generates the conversion signal. A frequency power detector generates frequency information and power information using the conversion signal. A symptom detector generates determination information for determining an early electromagnetic wave abnormality using the frequency information and the power information. An MCU executes one of a plurality of control modes to control the operation of at least one of the receiving end and the switch according to the determination information.

### CROSS-REFERENCE TO RELATED APPLICATION

The present application claims priority to Korean Patent Application No. 10-2023-0182316, filed on Dec. 14, 2023, the entire contents of which is incorporated herein for all purposes by this reference.

### BACKGROUND OF THE PRESENT DISCLOSURE

### Field of the Present Disclosure

The present disclosure relates to electromagnetic wave detection technology, and more particularly, to a device for detecting a precursor symptom of an early abnormality in a system and a method of controlling the same.

### DESCRIPTION OF RELATED ART

In response to the development of electrification, such as in autonomous vehicles, complex signal systems and high-power systems are coexisting and developing. In particular, vehicles have a risk of collision with pedestrians, other vehicles, and buildings therearound due to a malfunction or a driver's misbehavior, and various systems are required to prevent such a problem.

In recent years, vehicles are provided with various signal transmission systems such as sensors, actuators, displays, and the like for autonomous driving, entertainment, and information. In this regard, a high power electromagnetic (EM) field and a high frequency signaling system coexist.

Furthermore, to reduce weight and cost, various signals are often multiplexed on a single signal line, increasing the possibility of catastrophic consequences from signal line failures.

Multiple protection systems have been designed and are in operation to prevent such failures in electronic systems, but construction of additional failure detection systems in parallel with such protection systems is important for the safety of systems.

Furthermore, electromagnetic interference (EMI) from electromagnetic waves affects the reliable operation of electronics. The impact of EMI on systems is increasing due to increasing data transfer rates and energy minimization for low power.

Intentional electromagnetic interference (IEMI) is not EMI caused by the components of the system, but high-energy EMI with a malicious intent.

As highly complex systems such as autonomous driving are used, new attempts to attack such systems are emerging. Attempts to disable or misbehave systems such as vehicles, drones, and robots are expected to continue to evolve. As a result, it becomes increasingly important to detect such deliberate attacks at an early stage and to develop countermeasures accordingly.

Similarly, a variety of EMI is generated by the electrical wiring in the vehicle. The nature of such EMI varies significantly depending on the operating state of the vehicle.

For example, vehicles are subject to vibrations and/or shock due to the nature thereof. Accordingly, due to imperfect contact, imperfect grounding, broken or damaged sheaths and shields, and the like, a signaling system and/or a power transmission system may have significantly different characteristics compared to the initial state.

Experimentally, when cables are subjected to repeated folding endurance tests, the EMI characteristics of the cables change and generate more EMI signals. Detection of such EMI may be used as a precursor to a mechanical failure in cables, leading to safer systems.

However, a system for detecting such electromagnetic waves includes a relatively large volume and is controlled by a separate computer or the like. Accordingly, it is difficult to implement the system as a small, lightweight, low-power, and low-cost system, and it is impossible to embed and use a plurality of detection systems in the system.

The information included in this Background of the present disclosure is only for enhancement of understanding of the general background of the present disclosure and may not be taken as an acknowledgement or any form of suggestion that this information forms the prior art already known to a person skilled in the art.

### BRIEF SUMMARY

Various aspects of the present disclosure are directed to providing an early electromagnetic wave abnormality detection device configured so that a frequency detector including a fast response rate and a function of classifying electromagnetic waves and generating a warning signal by analyzing the detection signal are embedded in a single chip device, whereby an electromagnetic wave abnormality may be detected at an early stage, and a method of controlling the same.

Furthermore, another objective of the present disclosure is to provide an early electromagnetic wave abnormality detection device which may be implemented as a small, lightweight, low-power, and low-cost device and may be disposed in a plurality in a system for detecting electromagnetic waves and a method of controlling the same.

Furthermore, another objective of the present disclosure is to provide an early electromagnetic wave abnormality detection device configured to detect a cause and/or situation of electromagnetic waves, enabling a suitable countermeasure to be provided accordingly, and a method of controlling the same.

In one aspect, the present disclosure provides an early electromagnetic wave abnormality detection device configured so that a frequency detector including a fast response rate and a function of classifying electromagnetic waves and generating a warning signal by analyzing the detection signal are embedded in a single chip device, whereby an electromagnetic wave abnormality may be detected at an early stage.

The early electromagnetic wave abnormality detection device includes: a receiving end portion configured to receive at least one antenna signal from an antenna block and generate at least one conversion signal; a switch operably connected to the receiving end portion and configured to perform switching to change a gain according to characteristics of the at least one antenna signal and generate the at least one conversion signal; a frequency power detector operably connected to the switch and configured to generate frequency information and power information using the at least one conversion signal; a symptom detector operably connected to the frequency power detector and configured to generate determination information for determining an early electromagnetic wave abnormality using the frequency information and the power information; and a micro control unit (MCU) operably connected to the symptom detector and configured to execute one control mode among a plurality of control modes to control an operation of at least one of the receiving end portion and the switch according to the determination information.

Furthermore, the receiving end portion, the switch, the frequency power detector, and the symptom detector may be embedded in a single chip device.

Furthermore, the receiving end portion may include at least one amplifier configured in parallel.

Furthermore, the at least one amplifier may be a variable gain amplifier, and may perform variable gain amplification under control of the symptom detector.

Furthermore, the frequency power detector may include at least one frequency power detector configured in parallel.

Furthermore, the frequency power detector may include: a frequency generator configured to generate phase frequency signals including different phases; a mixer operably connected to the frequency generator and configured to mix the conversion signal and the phase frequency signals to generate a synthesized signal; a filter operably connected to the mixer and configured to filter the synthesized signal to generate a real number signal and an imaginary number signal; an adder operably connected to the filter and configured to multiply the real number signal and the imaginary number signal to generate power information of electromagnetic waves; and an analog-digital converter (ADC) operably connected to the adder and configured to convert the power information from analog information to digital information.

Furthermore, as the one control mode is executed, the symptom detector may compare a waveform of the input antenna signal with a predetermined normal operation waveform, and when the waveform of the input antenna signal is not similar to the predetermined normal operation waveform, determine the antenna signal to be an abnormal signal.

Furthermore, the plurality of control modes may include a normal control mode in which the antenna signal is processed as a normal signal, an electromagnetic interference (EMI) control mode in which the antenna signal is processed as an EMI signal, and an intentional electromagnetic interference (IEMI) control mode in which the antenna signal is processed as an IEMI signal.

Furthermore, in the EMI control mode, at least one of the receiving end portion and the switch may be controlled so that the antenna signal has predetermined high sensitivity and a low noise level, and in the IEMI control mode, the receiving end portion may be attenuated so that the antenna signal is maintained in a predetermined saturated state.

Furthermore, the switch may include a structure to select one input among a plurality of inputs and produce one output.

Furthermore, the switch may include at least one switching element connected to at least one amplifier provided in parallel in the receiving end portion in one-to-one correspondence.

In another aspect, provided is a method of controlling an early electromagnetic wave abnormality detection device, the method including: receiving by a receiving end portion at least one antenna signal from an antenna block and generating at least one conversion signal; performing, by a switch, switching to change a gain according to characteristics of the at least one antenna signal and generate the at least one conversion signal; generating, by a frequency power detector, frequency information and power information using the at least one conversion signal; generating, by a symptom detector, determination information for determining an early electromagnetic wave abnormality using the frequency information and the power information; and executing, by a micro control unit (MCU), one control mode among a plurality of control modes to control an operation of at least one of the receiving end portion and the switch according to the determination information.

Furthermore, the generation of the frequency information and the power information may include: generating, by a frequency generator, phase frequency signals including different phases; mixing, by a mixer, the conversion signal and the phase frequency signals to generate a synthesized signal; filtering, by a filter, the synthesized signal to generate a real number signal and an imaginary number signal; multiplying, by an adder, the real number signal and the imaginary number signal to generate power information of electromagnetic waves; and converting, by an analog-digital converter (ADC), the power information from analog information to digital information.

Furthermore, the generation of the determination information may include: as the one control mode is executed, comparing, by the symptom detector, a waveform of the input antenna signal with a predetermined normal operation waveform; and when the waveform of the input antenna signal is not similar to the predetermined normal operation waveform as a result of the comparison, determining the antenna signal to be an abnormal signal.

In another aspect, provided is an early electromagnetic wave abnormality detection system including: at least two system-on-chips in each of which the early electromagnetic wave abnormality detection device described above is embedded; and a controller electrically and communicatively connected to one of the at least two system-on-chips to perform control.

Furthermore, the at least two system-on-chips may be connected in a form of a daisy chain.

According to an exemplary embodiment of the present disclosure, a frequency detector including a fast response rate and a function of classifying electromagnetic waves and generating a warning signal by analyzing the detection signal are embedded in a single chip device, providing an early electromagnetic wave abnormality detection structure. Accordingly, the structure may be programmed to realize compactness, low power, and a variety of functions, being used as an electromagnetic wave detection system, such as for intentional electromagnetic interference (IEMI) and electromagnetic interference (EMI).

Furthermore, according to an exemplary embodiment of the present disclosure, it is possible to implement a detection system for determining the frequency-specific and time-specific features of electromagnetic signals with nanosecond precision.

Furthermore, according to an exemplary embodiment of the present disclosure, the optimal conditions for reporting an abnormality may be programmed and used as a reporting system. Accordingly, a low-power, low-cost, and miniaturized electromagnetic detection system may be provided.

The methods and apparatuses of the present disclosure have other features and advantages which will be apparent from or are set forth in more detail in the accompanying drawings, which are incorporated herein, and the following Detailed Description, which together serve to explain certain principles of the present disclosure.

### BRIEF DESCRIPTION OF THE DRAWINGS

FIG. 1 is a block diagram illustrating a configuration of an electromagnetic wave detection system according to an exemplary embodiment of the present disclosure.

FIG. 2 is a block diagram illustrating a specific configuration of the early electromagnetic wave abnormality detection device illustrated in FIG. 1.

FIG. 3 is a block diagram illustrating a specific configuration of the switch illustrated in FIG. 2.

FIG. 4 is a block diagram illustrating a specific configuration of the frequency detector illustrated in FIG. 2.

FIG. 5 is a block diagram illustrating a specific configuration of the symptom detector illustrated in FIG. 2.

FIG. 6 is a flowchart illustrating a process of detecting an early electromagnetic wave abnormality and performing a control mode in response to the detection according to an exemplary embodiment of the present disclosure.

FIG. 7 is a waveform diagram illustrating abnormal and normal operations of electromagnetic waves according to an exemplary embodiment of the present disclosure.

FIG. 8 is a conceptual diagram illustrating an early electromagnetic wave abnormality detection system, in which early electromagnetic wave abnormality detection devices according to an exemplary embodiment of the present disclosure are embedded in single chips, which are configured in a form of a daisy chain and connected to a controller.

It may be understood that the appended drawings are not necessarily to scale, presenting a somewhat simplified representation of various features illustrative of the basic principles of the present disclosure. The specific design features of the present disclosure as included herein, including, for example, specific dimensions, orientations, locations, and shapes will be determined in part by the particularly intended application and use environment.

In the figures, reference numbers refer to the same or equivalent portions of the present disclosure throughout the several figures of the drawing.

### DETAILED DESCRIPTION

Reference will now be made in detail to various embodiments of the present disclosure(s), examples of which are illustrated in the accompanying drawings and described below. While the present disclosure(s) will be described in conjunction with exemplary embodiments of the present disclosure, it will be understood that the present description is not intended to limit the present disclosure(s) to those exemplary embodiments of the present disclosure. On the other hand, the present disclosure(s) is/are intended to cover not only the exemplary embodiments of the present disclosure, but also various alternatives, modifications, equivalents and other embodiments, which may be included within the spirit and scope of the present disclosure as defined by the appended claims.

The foregoing objects, features, and advantages will be further described in detail with reference to the accompanying drawings, by which those including ordinary skill in the art to which the present disclosure pertains may readily practice the technical ideas of the present disclosure. In description of the present disclosure, detailed description will be omitted where it is considered that a detailed description of the known art to which the present disclosure relates would unnecessarily obscure the essence of the present disclosure. Hereinafter, example embodiments of the present disclosure will be described in detail with reference to the accompanying drawings. In the drawings, like reference numerals will be used to designate the same or similar components.

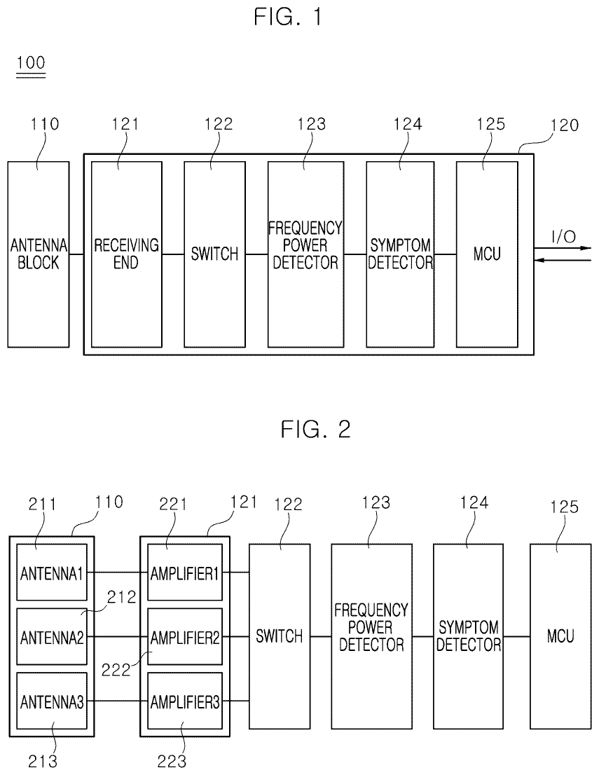

FIG. 1 is a block diagram illustrating a configuration of an electromagnetic wave detection system 100 according to an exemplary embodiment of the present disclosure. Referring to FIG. 1, the electromagnetic wave detection system 100 includes an antenna block 110 generating an antenna signal, an early electromagnetic wave abnormality detection device 120 configured to receive the antenna signal and detect an electromagnetic wave abnormality at an early stage, and the like.

The antenna block 110 includes a plurality of antennae to perform the function of generating antenna signals. The antenna signals may be radio frequency (RF) signals.

The early electromagnetic wave abnormality detection device 120 is configured to perform the function of receiving a plurality of antenna signals from the antenna block 110 and classifying the electromagnetic waves to detect a symptom. In this regard, the early electromagnetic wave abnormality detection device 120 may include: a receiving end portion 121 configured to receive an antenna signal and generate a plurality of conversion signals; a switch 122 configured to switch and change a gain according to characteristics of the received antenna signal; a frequency power detector 123 configured to generate frequency information and power information using the conversion signals connected according to the switching of the switch 122; a symptom detector 124 configured to early detect an electromagnetic wave abnormality using the frequency information and the power information; a micro control unit (MCU) 125 configured to early detect an electromagnetic wave abnormality using the frequency control the above-described components; and the like.

The receiving end portion 121 is connected to the antenna block 110 and is configured to perform the function of receiving an antenna signal and converting the antenna signal to generate a conversion signal.

The switch 122 is configured to perform the function of changing the gain according to the magnitude of the antenna signal received at the receiving end portion 121 to generate a conversion signal and connecting the conversion signal to the frequency power detector 123.

The frequency power detector 123 is configured to perform the function of generating the frequency information and/or the power information by processing the conversion signal connected by the switch 122.

The symptom detector 124 is configured to perform the function of determining an early electromagnetic wave abnormality by detecting power and a frequency over time using the frequency information and/or the power information, and generating and transmitting determination information to the MCU 125. The determination information is information indicating whether the current antenna signal is an EMI signal or an IEMI signal.

The MCU 125 is configured to perform the function of providing overall control of the early electromagnetic wave abnormality detection device 120. That is, the MCU 125 is configured to perform the function of controlling the components such as the receiving end portion 121, the switch 122, the frequency power detector 123, and the symptom detector 124. Here, some of the components may transmit and receive signals and/or data.

The MCU 125 is configured to control the receiving end portion 121 and/or the switch 122 in a plurality of operating modes based on the determination information received from the symptom detector 124. Because the EMI and the IEMI differ significantly in the power levels thereof, the receiving end portion 121 and/or the switch 122 are controlled to have high sensitivity and a low noise level in the case of EMI detection. Such a control scheme is referred to as an EMI control mode.

On the other hand, in the case of IEMI detection, the MCU 125 is configured to perform the control to prevent saturation of an input circuitry by attenuating the receiving end portion 121. Such a control scheme is referred to as an IEMI control mode.

Furthermore, the MCU 125 also is configured to perform functions such as communication with higher level controllers, self-testing, and self-diagnostics of SoC. A program is provided for the present purpose.

The MCU 125 may include a microprocessor, a microcomputer, memory, and the like.

The symptom detector 124 and the MCU 125 are provided separately in FIG. 1, but the symptom detector 124 may be provided inside the MCU 125.

FIG. 2 is a block diagram illustrating a specific configuration of the early electromagnetic wave abnormality detection device 120 illustrated in FIG. 1. Referring to FIG. 2, the antenna block 110 includes first, second, and third antennae 211, 212, and 213 provided in parallel. The first, second, and third antennae 211, 212, and 213 may be of the same type, or may be of different types depending on the wave. Each of the first, second, and third antennae 211, 212, and 213 may be, for example, a dipole, monopole, horn, or patch antenna.

Furthermore, the first, second, and third antennae 211, 212, and 213 may be positioned at physically different locations to detect time differences in the arrival of electromagnetic waves.

In contrast, the first, second, and third antennae 211, 212, and 213 may be antennae directed in their respective directions in a form of X/Y/Z.

The receiving end portion 121 may include an input port for receiving antenna signals from the first, second, and third antennae 211, 212, and 213, first, second, and third amplifiers 221, 222 and 223, and the like. The antenna block 110 and the receiving end portion 121 are connected by a wired medium such as coaxial cable.

The first, second, and third amplifiers 221, 222 and 223 may be provided in parallel, and may be variable gain amplifiers (VGAs). Such a variable gain amplifier (VGA) is configured to perform variable gain amplification under the control of the MCU 125.

The switch 122 is configured to connect any input to the frequency power detector 123. The switch 122 is configured to connect one of the conversion signals generated by the first, second, and third amplifiers 221, 222 and 223 to the frequency power detector 123.

The frequency power detector 123 is configured to perform the function of generating the frequency information and the power information from the conversion signal.

The symptom detector 124 obtains the frequency information and/or the power information from the frequency power detector 123 to detect an electromagnetic wave abnormality.

The number of the antennae 211, 212, and 213, the number of the amplifiers 221, 222, and 223, and the number of the frequency power detector 123 illustrated in FIG. 2 are for illustrative purposes only, are not intended thereto, and may be greater.

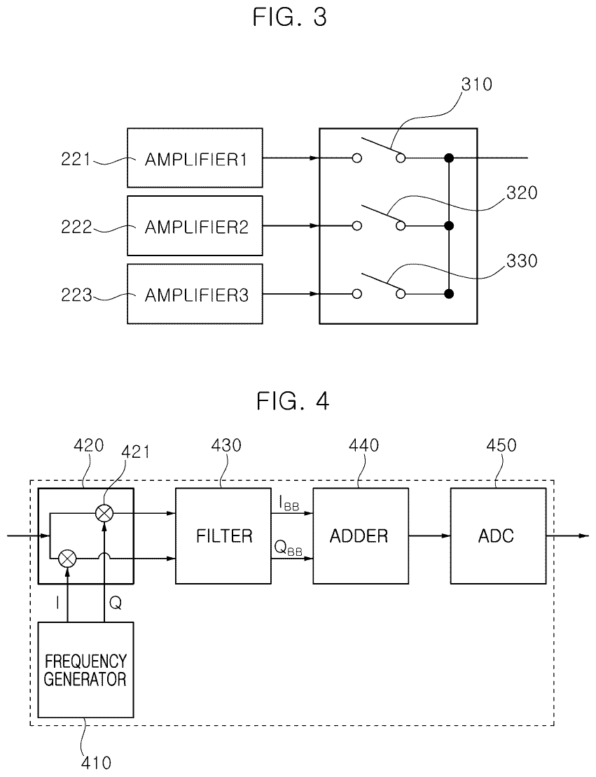

FIG. 3 is a block diagram illustrating a specific configuration of the switch 122 illustrated in FIG. 2. Referring to FIG. 3, the switch 122 is configured to connect one of outputs of each of the amplifiers 221, 222 and 223 to the frequency detector 123 in the next section. In other words, first, second, and third switching elements 310, 320, and 330 are connected to the first, second, and third amplifiers 221, 222, and 223 in one-to-one correspondence. The outputs of the first, second, and third switching elements 310, 320, and 330 are connected as one. That is, the switch 122 is internally configured in a form of an analog multiplexer to select one of a plurality of inputs and produce one output.

The first, second, and third switching elements 310, 320, and 330 may be field effect transistors (FETs), metal oxide semiconductor FETs (MOSFETs), or the like. An MOSFET includes a complementary metal oxide semiconductor (CMOS) structure.

FIG. 4 is a block diagram illustrating a specific configuration of the frequency detector 123 illustrated in FIG. 2. Referring to FIG. 4, the frequency detector 123 may include a frequency generator 410, a mixer 420, a filter 430, an adder 440, an analog-to-digital converter (ADC) 450, and the like.

The frequency generator 410 generates phase frequency signals including different phases. The frequency generator 410 is configured to generate frequencies that are 90° out of phase with each other. The frequency generator 410 generates an in-phase (I) frequency and a quadrature-phase (Q) frequency that are 90° out of phase with each other.

The mixer 420 mixes the conversion signal connected through the switch 122 with the phase frequency signals. That is, the mixer 420 is configured to multiply the in-phase frequency by a multiplier 421 and to multiply the conversion signal with the Q frequency to generate a two-dimensional synthesized signal. The mixer 420 is a quadrature down conversion mixer that is configured to perform a down conversion function for the input signal.

The filter 430 filters the synthesized signal to generate a real number signal IBB and an imaginary number signal QBB. The filter 430 may be a low pass filter. Thus, the filter 430 filters out only signals that are in the corresponding frequency band for the synthesized signal to generate the real number signal IBB and the imaginary number signal QBB. Here, BB refers to base band.

The adder 440 is configured to perform the function of generating a sum-of-squares signal (i.e., the power information of the electromagnetic wave) by summing the squares of the real number signal IBB and the imaginary number signal QBB. That is, the power (P) is

$$P = {I}_{BB}^{2} + {Q}_{BB}^{2} .$$

The ADC 450 is configured to perform the function of converting analog power information to digital power information. That is, the ADC 450 converts the power information from analog to digital.

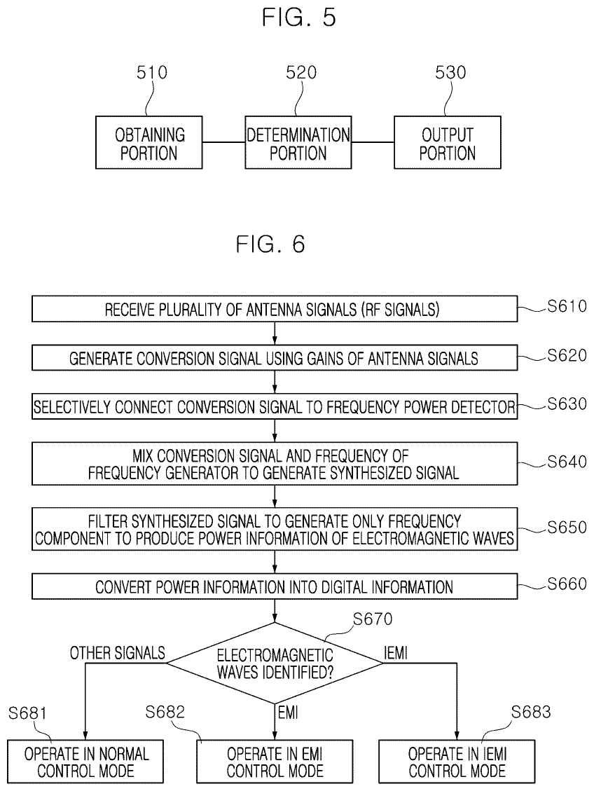

FIG. 5 is a block diagram illustrating a specific configuration of the symptom detector 124 illustrated in FIG. 2. Referring to FIG. 5, the symptom detector 124 may include an obtaining portion 510 obtaining the power information and/or the frequency information, a determination portion 520 comparing the obtained power information with a predetermined reference power value, and based on a comparison result, generating determination information by which an early electromagnetic wave abnormality is determined, an output portion 530 transmitting the determination information to the MCU 125, and the like.

The obtaining portion 510 is configured to perform the function of obtaining, from the frequency power detector 123, power information, frequency information, and the like stored therein.

The determination portion 520 compares the obtained power information with the predetermined reference power value, is configured to determine the current antenna signal input as an EMI signal, an IEMI signal, or a normal signal based on the comparison result, and generates the determination information. The determination portion 520 is configured to determine whether the current antenna signal is in the magnitude range of the EMI, IEMI, or normal signal, and if so, is configured to determine the antenna signal as abnormal or normal, and generates the determination information.

Furthermore, the determination portion 520 is configured to perform the function of reading and analyzing the frequency information and/or the power information generated by the frequency power detector 123 and detecting an abnormal signal. The determination portion 520 is configured to extract features of the currently input frequency and transmits the extracted features to a higher level controller via the MCU 125 and an input/output (I/O) interface.

The higher level controller is configured to determine the operation mode of the early electromagnetic wave abnormality detection device 120 via the I/O interface and is configured to perform necessary processing when a signal of a certain pattern is detected. The higher level controller may be an electric control unit (ECU), a hybrid control unit (HCU), or the like.

The output portion 530 is configured to perform the function of transmitting the determination information to the MCU 125.

The obtaining portion 510, the determination portion 520, and the output portion 530 illustrated in FIG. 5 respectively refer to a unit that handles at least one function or operation, which may be implemented as software and/or hardware. In hardware implementation, such a component may be implemented as any device designed to perform the functions described above, such as an application specific integrated circuit (ASIC), a digital signal processor (DSP), a programmable logic device (PLD), a field programmable gate array (FPGA), a processor, a microprocessor, another electronic unit, or a combination thereof.

Software implementations may include software components (or elements), object-oriented software components, class components, and task components, processes, functions, attributes, procedures, subroutines, program code segments, drivers, firmware, microcode, data, database, data structures, tables, arrays, and variables. The software, data, and the like may be stored in memory and executed by a processor. The memory or processor may employ a variety of means well known to those skilled in the art.

FIG. 6 is a flowchart illustrating a process of detecting an early electromagnetic wave abnormality and performing a control mode in response to the detection according to an exemplary embodiment of the present disclosure. Referring to FIG. 6, the early electromagnetic wave abnormality detection device 120 receives a plurality of antenna signals from the antenna block 110 (step S610).

Thereafter, the receiving end portion 121 adjusts the gain of the received antenna signal to generate a conversion signal (step S620).

Subsequently, the switch 122 selectively connects the conversion signal to the frequency power detector 123 (step S630).

Thereafter, the frequency power detector 123 mixes the conversion signal and the frequency of the frequency generator 410 to generate a synthesized signal (step S640).

Subsequently, the frequency power detector 123 filters the synthesized signal to generate only set frequency components to produce power information of the electromagnetic wave, converts the power information into digital information, and transmits the converted power information to the symptom detector 124 (steps S650 and S660).

Thereafter, the symptom detector 124 obtains digital information from the frequency power detector 123 and compares the power of the current antenna signal with a predetermined power reference value to determine the current antenna signal as normal, EMI, or IEMI (step S670).

When the current antenna signal is a normal signal according to the determination result of step S670, the MCU 125 operates the receiving end portion 121 and/or the switch 122 in a normal control mode (step S681). That is, a normal signal refers to a signal which is not an EMI or IEMI signal.

Furthermore, when the current antenna signal corresponds to the EMI signal according to the determination result of step S670, the MCU 125 operates the receiving end portion 121 and/or the switch 122 in an EMI control mode (step S682).

Furthermore, when the current antenna signal corresponds to the IEMI signal according to the determination result of step S670, the MCU 125 operates the receiving end portion 121 and/or the switch 122 in an IEMI control mode (step S683).

In other words, it is possible to switch between two or more control modes in a short time. Furthermore, the switch 122 allows simultaneous processing with a low level signal input or a low noise mode and a high level signal input. In the case of low level signal input, a lower noise level is achieved by applying time averaging.

In other words, a low level signal is not an EMI or IEMI signal, but is noise which is relatively similar to a signal. The present case may be only detected when there is a relative increase in noise due to a crosstalk or a short circuit in a ground, shield, or the like of wiring.

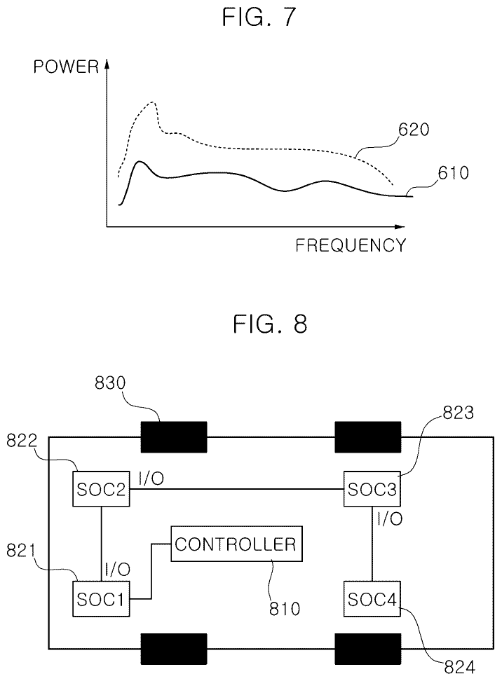

FIG. 7 is a waveform diagram illustrating abnormal and normal operations of electromagnetic waves according to an exemplary embodiment of the present disclosure. FIG. 7 is a conceptual diagram illustrating whether a detected antenna signal is indicative of an abnormality after operation in the normal control mode, the EMI control mode, and the IEMI control mode in FIG. 6. In FIG. 7, the case of an EMI pattern will be taken as an example for convenience in the description.

In the EMI pattern, a predetermined normal operation waveform 610 and an abnormal operation waveform 620 are illustrated. Therefore, when the abnormal operation waveform 620 appears by comparison with the stored predetermined normal operation waveform 610, the symptom detector 124 is configured to determine the abnormal operation waveform to be an abnormal signal and transmits the abnormal operation waveform to the MCU 125. That is, when the currently input EMI waveform is not similar to the normal operation waveform 610, the corresponding EMI signal is determined to be an abnormal signal. The MCU 125 may transmit the EMI signal to the higher level controller via the I/O interface.

FIG. 8 is a conceptual diagram illustrating an early electromagnetic wave abnormality detection system 800, in which the early electromagnetic wave abnormality detection devices 120 according to an exemplary embodiment of the present disclosure are embedded in single system-on-chips (SoCs) 821, 822, 823 and 824, which are configured in a form of a daisy chain and connected to the controller 810. That is, the early electromagnetic wave abnormality detection system 800 is implemented inside a vehicle including wheels 830.

The first, second, third and fourth system-on-chips 821, 822, 823 and 824 are configured in a form of a daisy chain. The first single chip 821 is connected to the controller 810.

The controller 810 is connected to the MCU 125 as a higher level controller to transmit and receive signals and data. In this regard, the controller 810 may include a microprocessor, a microcomputer, memory, a communication circuit, and the like. The memory may include a combination of non-volatile memory, such as flash memory, electrically erasable programmable read-only memory (EEPROM), static RAM (SRAM), ferro-electric RAM (FRAM), phase-change RAM (PRAM), and magnetic RAM (MRAM), and/or volatile memory, such as dynamic random access memory (DRAM), synchronous dynamic random access memory (SDRAM), and double data rate-SDRAM (DDR-SDRAM).

Furthermore, the methods or the steps of the algorithms described with respect to the exemplary embodiments included herein may be implemented directly in hardware, implemented as software modules executed by hardware, or a combination thereof.

Software modules may be embedded in random access memory (RAM), read only memory (ROM), erasable programmable ROM (EPROM), electrically erasable programmable ROM (EEPROM), or flash memory.

In various exemplary embodiments of the present disclosure, each operation described above may be performed by a control device, and the control device may be configured by a plurality of control devices, or an integrated single control device.

In various exemplary embodiments of the present disclosure, the memory and the processor may be provided as one chip, or provided as separate chips.

In various exemplary embodiments of the present disclosure, the scope of the present disclosure includes software or machine-executable commands (e.g., an operating system, an application, firmware, a program, etc.) for enabling operations according to the methods of various embodiments to be executed on an apparatus or a computer, a non-transitory computer-readable medium including such software or commands stored thereon and executable on the apparatus or the computer.

In various exemplary embodiments of the present disclosure, the control device may be implemented in a form of hardware or software, or may be implemented in a combination of hardware and software.

Furthermore, the terms such as “unit”, “module”, etc. included in the specification mean units for processing at least one function or operation, which may be implemented by hardware, software, or a combination thereof.

In an exemplary embodiment of the present disclosure, the vehicle may be referred to as being based on a concept including various means of transportation. In some cases, the vehicle may be interpreted as being based on a concept including not only various means of land transportation, such as cars, motorcycles, trucks, and buses, that drive on roads but also various means of transportation such as airplanes, drones, ships, etc.

For convenience in explanation and accurate definition in the appended claims, the terms “upper”, “lower”, “inner”, “outer”, “up”, “down”, “upwards”, “downwards”, “front”, “rear”, “back”, “inside”, “outside”, “inwardly”, “outwardly”, “interior”, “exterior”, “internal”, “external”, “forwards”, and “backwards” are used to describe features of the exemplary embodiments with reference to the positions of such features as displayed in the figures. It will be further understood that the term “connect” or its derivatives refer both to direct and indirect connection.

The term “and/or” may include a combination of a plurality of related listed items or any of a plurality of related listed items. For example, “A and/or B” includes all three cases such as “A”, “B”, and “A and B”.

In exemplary embodiments of the present disclosure, “at least one of A and B” may refer to “at least one of A or B” or “at least one of combinations of at least one of A and B”. Furthermore, “one or more of A and B” may refer to “one or more of A or B” or “one or more of combinations of one or more of A and B”.

In the present specification, unless stated otherwise, a singular expression includes a plural expression unless the context clearly indicates otherwise.

In the exemplary embodiment of the present disclosure, it should be understood that a term such as “include” or “have” is directed to designate that the features, numbers, steps, operations, elements, parts, or combinations thereof described in the specification are present, and does not preclude the possibility of addition or presence of one or more other features, numbers, steps, operations, elements, parts, or combinations thereof.

According to an exemplary embodiment of the present disclosure, components may be combined with each other to be implemented as one, or some components may be omitted.

Hereinafter, the fact that pieces of hardware are coupled operably may include the fact that a direct and/or indirect connection between the pieces of hardware is established by wired and/or wirelessly.

The foregoing descriptions of specific exemplary embodiments of the present disclosure have been presented for purposes of illustration and description. They are not intended to be exhaustive or to limit the present disclosure to the precise forms disclosed, and obviously many modifications and variations are possible in light of the above teachings. The exemplary embodiments were chosen and described in order to explain certain principles of the invention and their practical application, to enable others skilled in the art to make and utilize various exemplary embodiments of the present disclosure, as well as various alternatives and modifications thereof. It is intended that the scope of the present disclosure be defined by the Claims appended hereto and their equivalents.

What is claimed is:

1. An early electromagnetic wave abnormality detection apparatus comprising:
a receiving end portion configured to receive at least one antenna signal from an antenna block and generate at least one conversion signal;
a switch operably connected to the receiving end portion and configured to perform switching to change a gain according to characteristics of the at least one antenna signal and generate the at least one conversion signal;
a frequency power detector operably connected to the switch and configured to generate frequency information and power information using the at least one conversion signal;
a symptom detector operably connected to the frequency power detector and configured to generate determination information for determining an early electromagnetic wave abnormality using the frequency information and the power information; and
a micro control unit (MCU) operably connected to the symptom detector and configured to execute one control mode among a plurality of control modes to control an operation of at least one of the receiving end portion and the switch according to the determination information.

2. The early electromagnetic wave abnormality detection apparatus of claim 1, wherein the receiving end portion, the switch, the frequency power detector, and the symptom detector are embedded in a single chip device.

3. The early electromagnetic wave abnormality detection apparatus of claim 1, wherein the receiving end portion includes at least one amplifier configured in parallel.

4. The early electromagnetic wave abnormality detection apparatus of claim 3, wherein the at least one amplifier is a variable gain amplifier, and is configured to perform variable gain amplification under control of the symptom detector.

5. The early electromagnetic wave abnormality detection apparatus of claim 1, wherein the frequency power detector includes:
a frequency generator configured to generate phase frequency signals including different phases;
a mixer operably connected to the frequency generator and configured to mix the at least one conversion signal and the phase frequency signals to generate a synthesized signal;
a filter operably connected to the mixer and configured to filter the synthesized signal to generate a real number signal and an imaginary number signal;
an adder operably connected to the filter and configured to multiply the real number signal and the imaginary number signal to generate power information of electromagnetic waves; and
an analog-digital converter (ADC) operably connected to the adder and configured to convert the power information from analog information to digital information.

6. The early electromagnetic wave abnormality detection apparatus of claim 1, wherein, in response that the one control mode is executed, the symptom detector compares a waveform of the at least one antenna signal with a predetermined normal operation waveform, and in response that the waveform of the input antenna signal is not similar to the predetermined normal operation waveform, is configured to determine the at least one antenna signal to be an abnormal signal.

7. The early electromagnetic wave abnormality detection apparatus of claim 1, wherein the plurality of control modes include a normal control mode in which the at least one antenna signal is processed as a normal signal, an electromagnetic interference (EMI) control mode in which the at least one antenna signal is processed as an EMI signal, and an intentional electromagnetic interference (IEMI) control mode in which the at least one antenna signal is processed as an IEMI signal.

8. The early electromagnetic wave abnormality detection apparatus of claim 7, wherein, in the EMI control mode, at least one of the receiving end portion and the switch is controlled so that the at least one antenna signal has predetermined sensitivity and a predetermined noise level, and in the IEMI control mode, the receiving end portion is attenuated so that the at least one antenna signal is maintained in a predetermined saturated state.

9. The early electromagnetic wave abnormality detection apparatus of claim 1, wherein the switch includes a structure to select one input among a plurality of inputs and produce one output.

10. The early electromagnetic wave abnormality detection apparatus of claim 9, wherein the switch includes at least one switching element connected to at least one amplifier provided in parallel in the receiving end portion in one-to-one correspondence.

11. A method of controlling an early electromagnetic wave abnormality detection device, the method comprising:
receiving by a receiving end portion, at least one antenna signal from an antenna block and generating at least one conversion signal;
performing, by a switch operably connected to the receiving end portion, switching to change a gain according to characteristics of the at least one antenna signal and generate the at least one conversion signal;
generating, by a frequency power detector operably connected to the switch, frequency information and power information using the at least one conversion signal;
generating, by a symptom detector operably connected to the frequency power detector, determination information for determining an early electromagnetic wave abnormality using the frequency information and the power information; and
executing, by a micro control unit (MCU) operably connected to the symptom detector, one control mode among a plurality of control modes to control an operation of at least one of the receiving end portion and the switch according to the determination information.

12. The method of claim 11, wherein the receiving end portion, the switch, the frequency power detector, and the symptom detector are embedded in a single chip device.

13. The method of claim 11, wherein the receiving end portion includes at least one amplifier configured in parallel.

14. The method of claim 13, wherein the at least one amplifier is a variable gain amplifier, and is configured to perform variable gain amplification under control of the symptom detector.

15. The method of claim 11,
wherein the frequency power detector includes a frequency generator, a mixer, a filter, an adder and an analog-digital converter (ADC), and
wherein the generation of the frequency information and the power information includes:
generating, by the frequency generator, phase frequency signals including different phases;
mixing, by the mixer operably connected to the frequency generator, the at least one conversion signal and the phase frequency signals to generate a synthesized signal;
filtering, by the filter operably connected to the mixer, the synthesized signal to generate a real number signal and an imaginary number signal;
multiplying, by the adder operably connected to the filter, the real number signal and the imaginary number signal to generate power information of electromagnetic waves; and
converting, by the analog-digital converter (ADC) operably connected to the adder, the power information from analog information to digital information.

16. The method of claim 11, wherein the generation of the determination information includes:
in response that the one control mode is executed, comparing, by the symptom detector, a waveform of the at least one antenna signal with a predetermined normal operation waveform; and
in response that the waveform of the at least one antenna signal is not similar to the predetermined normal operation waveform as a result of the comparing, determining the at least one antenna signal to be an abnormal signal.

17. The method of claim 11, wherein the plurality of control modes include a normal control mode in which the at least one antenna signal is processed as a normal signal, an electromagnetic interference (EMI) control mode in which the at least one antenna signal is processed as an EMI signal, and an intentional electromagnetic interference (IEMI) control mode in which the at least one antenna signal is processed as an IEMI signal.

18. The method of claim 17, wherein in the EMI control mode, at least one of the receiving end portion and the switch is controlled so that the at least one antenna signal has predetermined sensitivity and a predetermined noise level, and in the IEMI control mode, the receiving end portion is attenuated so that the at least one antenna signal is maintained in a predetermined saturated state.

19. An early electromagnetic wave abnormality detection system including:
at least two system-on-chips in each of which the early electromagnetic wave abnormality detection device as claimed in claim 1 is embedded; and
a controller electrically and communicatively connected to one of the at least two system-on-chips to perform control,
wherein the at least two system-on-chips are connected in a form of a daisy chain.
